(19) United States
(12) Patent Application Publication
(10) Pub. No.: US 2013/0048072 A1
(43) Pub. Date: Feb. 28, 2013

(54) SOLAR PHOTOVOLTAIC DEVICE AND A PRODUCTION METHOD FOR THE SAME

(71) Applicant: Chul Hwan Choi, Seoul (KR)

(72) Inventor: Chul Hwan Choi, Seoul (KR)

(73) Assignee: LG INNOTEK CO., LTD., Seoul (KR)

(21) Appl. No.: 13/638,173

(22) PCT Filed: Mar. 30, 2011
(86) PCT No.: PCT/KR2011/002188

§ 371 Date: Nov. 8, 2012

(30) Foreign Application Priority Data
Mar. 30, 2010 (KR) 10-2010-0028417

(51) Int. Cl. H01L 31/0216; H01L 31/18

(52) U.S. Cl. 136/256; 438/72; 257/E31.127

(57) ABSTRACT

Disclosed are a solar cell and a method of fabricating the same. The solar cell includes a back electrode layer; a light absorbing layer on the back electrode layer; a protrusion pattern on the light absorbing layer; a first anti-reflective layer having a first thickness on the protrusion pattern; and a second anti-reflective layer having a second thickness smaller than the first thickness on the protrusion pattern.

### TECHNICAL FIELD

The embodiment relates to a solar cell and a method of fabricating the same.

### BACKGROUND ART

Recently, as energy consumption is increased, a solar cell has been developed to convert solar energy into electrical energy.

In particular, a CIGS-based solar cell, which is a PN hetero junction apparatus having a substrate structure including a glass substrate, a metallic back electrode layer, a P type CIGS-based light absorbing layer, a high-resistance buffer layer, and an N type window layer, has been extensively used.

### DISCLOSURE

### Technical Problem

The embodiment provides a solar cell having an improved external appearance and high efficiency and a method of fabricating the same.

### Technical Solution

A solar cell according to the embodiment includes a back electrode layer; a light absorbing layer on the back electrode layer; a protrusion pattern on the light absorbing layer; a first anti-reflective layer having a first thickness on the protrusion pattern; and a second anti-reflective layer having a second thickness smaller than the first thickness on the protrusion pattern.

A method of fabricating a solar cell according to the embodiment includes the steps of forming a back electrode layer on a substrate; forming a light absorbing layer on the back electrode layer; forming a window layer including a protrusion pattern on the light absorbing layer; and forming first and second anti-reflective layers by depositing materials on the window layer while inclining a deposition direction of the materials.

### Advantageous Effects

The solar cell according to the embodiment includes the first and second anti-reflective layers, which are disposed on the protrusion pattern and having thicknesses different from each other. In particular, the first anti-reflective layer is disposed at one side of the protrusion pattern and the second reflective layer is disposed at the other side of the protrusion pattern.

Thus, the color of the window layer may be changed according to the viewing direction. This is because the wavelength causing the constructive interference in the first anti-reflective layer is different from the wavelength causing the constructive interference in the second anti-reflective layer.

Therefore, the solar cell according to the embodiment may have the improved external appearance.

In addition, the incident rate of the window layer may be increased due to the protrusion pattern, the first anti-reflective layer and the second anti-reflective layer. Thus, the efficiency of the solar cell according to the embodiment can be improved.

### DESCRIPTION OF DRAWINGS

FIG. 1 is a sectional view showing a solar cell according to the embodiment;

FIGS. 2 to 4 are perspective views showing various examples of anti-reflective patterns; and

FIGS. 5 to 7 are views showing the process for fabricating a solar cell according to the embodiment.

### BEST MODE

### Mode for Invention

In the description of the embodiments, it will be understood that when a substrate, a film, an electrode, a groove, or a layer is referred to as being “on” or “under” another substrate, another film, another electrode, another groove, or another layer, it can be “directly” or “indirectly” on the other substrate, the other film, the other electrode, the other groove, or the other layer, or one or more intervening layers may also be present. Such a position of the layer has been described with reference to the drawings. The size of the elements shown in the drawings may be exaggerated for the purpose of explanation and may not utterly reflect the actual size.

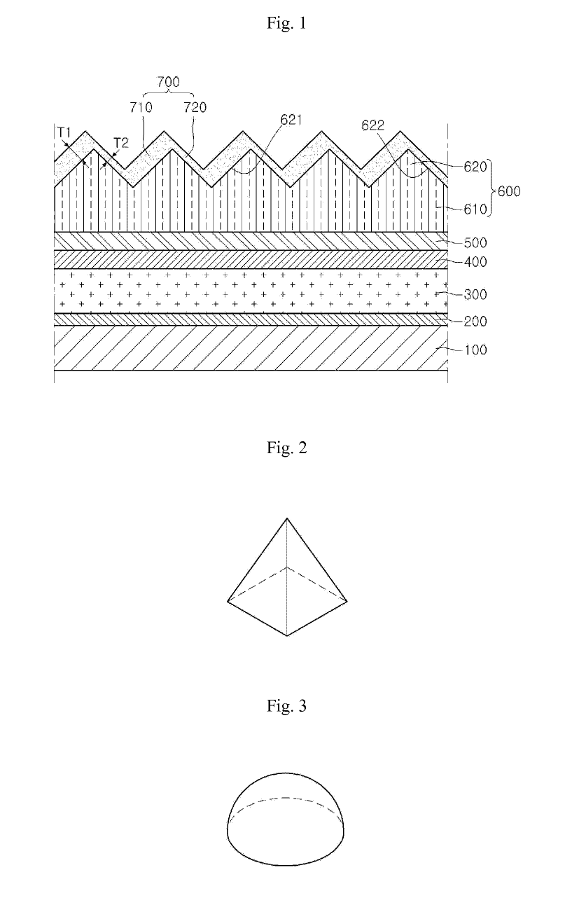

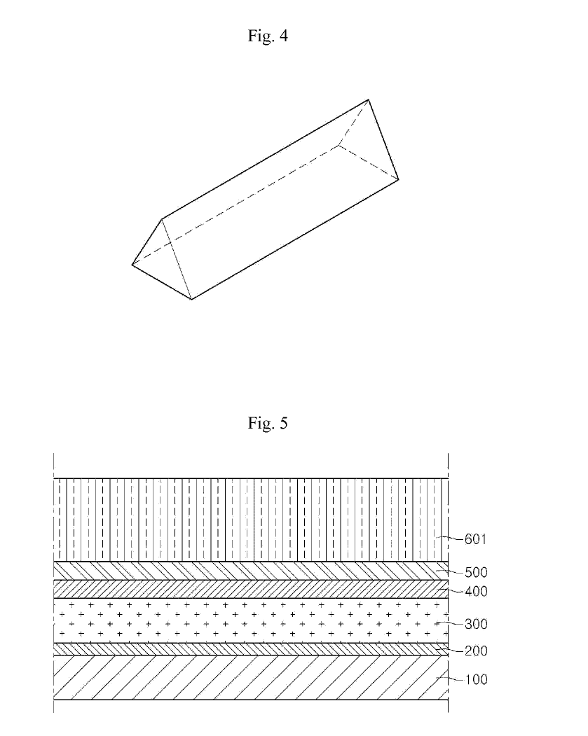

FIG. 1 is a sectional view showing a solar cell according to the embodiment, and FIGS. 2 to 4 are perspective views showing various examples of an anti-reflective pattern.

Referring to FIG. 1, the solar cell includes a support substrate 100, a back electrode layer 200, a light absorbing layer 300, a buffer layer 400, a high resistance buffer layer 500, a window layer 600, and an anti-reflective layer 700.

The support substrate 100 has a plate shape and supports the back electrode layer 200, the light absorbing layer 300, the buffer layer 400, the high resistance buffer layer 500, and the window layer 600.

The support substrate 100 may include an insulator. The support substrate 100 may include a glass substrate, a plastic substrate, or a metallic substrate. In more detail, the support substrate 100 may include a soda lime glass substrate. The support substrate 100 may be transparent or may be rigid or flexible.

The back electrode layer 200 is provided on the substrate 100. The back electrode layer 200 may be a conductive layer. The back electrode layer 200 may include a metal, such as molybdenum (Mo).

In addition, the back electrode layer 200 may include at least two layers. In this case, the layers may be formed by using the homogeneous metal or heterogeneous metals.

The light absorbing layer 300 is provided on the back electrode layer 200. The light absorbing layer 300 includes a group I-III-VI compound. For example, the light absorbing layer 300 may have a Cu(In,Ga)Se₂ (CIGS) crystal structure, a Cu(In)Se₂ crystal structure, or a Cu(Ga)Se₂ crystal structure.

The light absorbing layer 300 may have an energy bandgap in the range of about 1eV to about 1.8 eV.

The buffer layer 400 is provided on the light absorbing layer 300. The buffer layer 400 directly makes contact with the light absorbing layer 300.

The buffer layer 400 may include CdS. The buffer layer 400 may have the energy bandgap in the range of about 1.9 eV to about 2.3 eV.

The high resistance buffer layer 500 is provided on the buffer layer 400. The high-resistance buffer layer 500 may include iZnO, which is zinc oxide not doped with impurities. The high resistance buffer layer 500 has an energy bandgap in the range of about 3.1 eV to about 3.3 eV.

The window layer 600 is provided on the high resistance buffer layer 500. The window layer 600 is transparent, and includes a conductive layer. In addition, the window layer 600 may include Al doped ZnO (AZO).

The window layer 600 includes a base layer 610 and an anti-reflective pattern 620.

The base layer 610 is provided on the high resistance buffer layer 500. The anti-reflective pattern 620 protrudes from the base layer 610. In other words, the anti-reflective pattern 620 is a protrusion pattern. The base layer 610 may be integrally formed with the anti-reflective pattern 620.

As shown in FIGS. 2 to 4, the anti-reflective pattern 620 may have various shapes. For example, the anti-reflective pattern 620 may have a pyramid shape, a hemispheric shape, or a triangular prim shape.

The anti-reflective pattern 620 may have a height in the range of about 100 nm to about 500 nm. The height of the anti-reflective pattern 620 may correspond to about 10% to about 50% of the thickness of the window layer 600.

The anti-reflective pattern 620 includes first inclined surfaces 621 and second inclined surfaces 622.

The first inclined surfaces 621 are directed to a first direction. The first inclined surfaces 621 may extend in the same direction. The first inclined surfaces 621 are inclined with respect to a top surface of the support substrate 100. In other words, the first inclined surfaces 621 are inclined with respect to a top surface of the back electrode layer 200 and a top surface of the light absorbing layer 300.

An angle between the first inclined surfaces 621 and to top surface of the light absorbing layer 300 may be in the range of about 20° to about 60°. Similarly, an angle between the first inclined surfaces 621 and the top surface of the back electrode layer 200 may be in the range of about 20° to about 60°.

The second inclined surfaces 622 are directed to a second direction different from the first direction. The second inclined surfaces 622 may extend in the same direction. The second inclined surfaces 622 may face the first inclined surfaces 621. For example, the second inclined surfaces 622 are symmetrical to the first inclined surfaces 621.

The second inclined surfaces 622 are inclined with respect to the top surface of the support substrate 100. In other words, the second inclined surfaces 622 are inclined with respect to the top surface of the back electrode layer 200 and the top surface of the light absorbing layer 300.

An angle between the second inclined surfaces 622 and the top surface of the light absorbing layer 300 may be in the range of about 20° to about 60°. Similarly, an angle between the second inclined surfaces 622 and the top surface of the back electrode layer 200 may be in the range of about 20° to about 60°.

The anti-reflective layer 700 is provided on the window layer 600. The anti-reflective layer 700 is coated on the top surface of the window layer 600. In more detail, the anti-reflective layer 700 covers the anti-reflective pattern 620. The anti-reflective layer 700 is coated on the surface of the anti-reflective pattern 620.

The anti-reflective layer 700 is transparent. The anti-reflective layer 700 may include anti-reflective coating material such as MgF₂ or LiF.

The anti-reflective layer 700 includes a first anti-reflective layer 710 and a second anti-reflective layer 720.

The first anti-reflective layer 710 is provided on the first inclined surfaces 621. The first anti-reflective layer 710 is coated on the first inclined surfaces 621.

The first anti-reflective layer 710 has a first thickness T1 having a greater size. The first thickness T1 of the first anti-reflective layer 710 may be in the range of about 100 nm to about 500 nm.

The second anti-reflective layer 720 is provided on the second inclined surfaces 621. The second anti-reflective layer 720 is coated on the second inclined surfaces 622.

The second anti-reflective layer 720 has a second thickness T1 having a smaller size. The second thickness T2 of the second anti-reflective layer 720 may be in the range of about 50 nm to about 450 nm. The second thickness T2 is smaller than the first thickness T1. In this case, the difference between the first thickness T1 and the second thickness T2 may be in the range of about 10 nm to about 100 nm.

The first anti-reflective layer 710 is integrally formed with the second anti-reflective layer 720. In other words, the first anti-reflective layer 710 and the second anti-reflective layer 720 constitute one layer.

Since the first anti-reflective layer 710 and the second anti-reflective layer 720 have thicknesses T1 and T2 different from each other, the first anti-reflective layer 710 and the second anti-reflective layer 720 make constructive interference at wavelength bands different from each other.

In other words, an optical path difference between a first light reflected from the first anti-reflective layer 710 and a second light reflected from the first inclined surfaces 621 is twice greater than the first thickness T1. The first and second lights make constructive interference at a specific wavelength band due to the optical path difference.

Similarly, an optical path difference between a third light reflected from the second anti-reflective layer 720 and a fourth light reflected from the second inclined surfaces 622 is twice greater than the second thickness T2. The third and fourth lights make constructive interference at a specific wavelength band due to the optical path difference.

In this case, since the first thickness T1 is different from the second thickness T2, wavelength bands making constructive interference are different from each other. Accordingly, observed colors are different from each other.

Therefore, different colors may be observed according to viewing angles for the anti-reflective layer 700.

Therefore, the solar cell according to the embodiment can have an improved external appearance.

In addition, the light incident efficiency of the window layer 600 is improved due to the anti-reflective layer 700 and the anti-reflective pattern 620.

Therefore, the solar cell according to the embodiment can represent improved efficiency.

Although the present embodiment has been described in that the anti-reflective pattern 620 formed in the window layer 600 is coated with the anti-reflective layers 700 having thicknesses different from each other, the embodiment is not limited thereto. Accordingly, the embodiment may have a structure in which anti-reflective layers having different thicknesses are coated on the anti-reflective pattern 620 formed in a protective glass provided on the window layer 600.

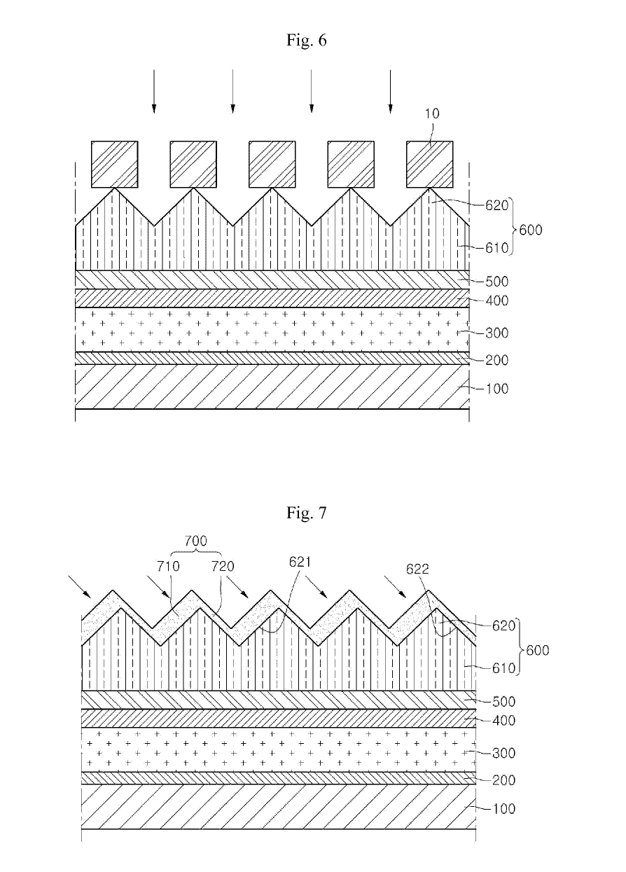

FIGS. 5 to 8 are sectional views showing the fabricating process of the solar cell according to the embodiment. Hereinafter, the present fabrication method will be described by making reference to the above description of the solar cell. The description of the present fabrication method will be incorporated in the above description of the solar cell.

Referring to FIG. 5, the back electrode layer 200 is formed by depositing a metal such as molybdenum (Mo) on the support substrate 100 through a sputtering process. The back electrode layer 200 may be formed through two processes having process conditions different from each other.

An additional layer such as an anti-diffusion layer may be interposed between the support substrate 100 and the back electrode layer 200.

The light absorbing layer 300 is formed on the back electrode layer 200.

The light absorbing layer 300 may be formed through a sputtering process or an evaporation scheme.

For example, the light absorbing layer 300 may be formed through various schemes such as a scheme of forming a Cu(In,Ga)Se2 (CIGS) based light absorbing layer 300 by simultaneously or separately evaporating Cu, In, Ga, and Se and a scheme of performing a selenization process after a metallic precursor layer has been formed.

Regarding the details of the selenization process after the formation of the metallic precursor layer, the metallic precursor layer is formed on the back electrode layer 200 through a sputtering process employing a Cu target, an In target, a Ga target or an alloy target.

Thereafter, the metallic precursor layer is subject to the selenization process so that the Cu (In, Ga) Se2 (CIGS) based light absorbing layer 300 is formed.

In addition, the sputtering process employing the Cu target, the In target, and the Ga target and the selenization process may be simultaneously performed.

Further, a CIS or a CIG based light absorbing layer 300 may be formed through the sputtering process employing only Cu and In targets or only Cu and Ga targets and the selenization process.

Thereafter, the buffer layer 400 is formed on the light absorbing layer 300. The buffer layer 400 may be formed by depositing CdS on the light absorbing layer 300 through a chemical bath deposition (CBD) process.

The high-resistance buffer layer 500 is formed by depositing zinc oxide on the buffer layer 400 through a sputtering process.

A preliminary window layer 601 is formed on the high resistance buffer layer 500. In order to form the preliminary window layer 601, a transparent conductive material is laminated on the high resistance buffer layer 500. The transparent conductive material may include AZO.

Referring to FIG. 6, a mask pattern 10 is formed on the preliminary window layer 601. The mask pattern 10 may be formed through a photolithography process.

Thereafter, the preliminary window layer 601 is etched by using an etching solution, thereby forming the window layer 600 including the base layer 610 and the anti-reflective pattern 620. The etching solution may include a hydrochloric acid solution.

In addition, the top surface of the preliminary window layer 601 may be subject to surface-treatment by using etching particles such as micro sands without employing the mask pattern.

Referring to FIG. 7, the anti-reflective layer 700 is formed on the window layer 600. In order to form the anti-reflective layer 700, a material used to form the anti-reflective layer 700 is deposited on the support substrate 100 while inclining a deposition direction of the material.

For example, MgF₂ or LiF particles are spread on the window layer 600 from an MgF₂ sputtering target or an LiF sputtering target while inclining a deposition direction of the MgF₂ or LiF particles. The spread direction of the above particles may be inclined at an angle of about 20° to about 60° with respect to the top surface of the support substrate 100.

The materials used to form the anti-reflective layer 700 are spread toward the first inclined surfaces 621.

Therefore, the first anti-reflective layer 710 having the first thickness T1 in a greater size is formed on the first inclined surfaces 621, and the second anti-reflective layer 720 having the second thickness T2 in a smaller size is formed on the second inclined surfaces 622.

As described above, according to the method of fabricating the solar cell of the embodiment, a solar cell having an improved external appearance and improved efficiency can be fabricated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1-19. (canceled)

20. A solar cell comprising:
a back electrode layer;
a light absorbing layer on the back electrode layer;
a protrusion pattern on the light absorbing layer;
a first anti-reflective layer having a first thickness on the protrusion pattern; and
a second anti-reflective layer having a second thickness smaller than the first thickness on the protrusion pattern.

21. The solar cell of claim 20, wherein the protrusion pattern includes first and second inclined surfaces, which are opposite to each other, the first anti-reflective layer is disposed on the first inclined surface, and the second anti-reflective layer is disposed on the second inclined surface.

22. The solar cell of claim 21, wherein an angle between the first inclined surface and a top surface of the back electrode layer and an angle between the second inclined surface and the top surface of the back electrode layer are in a range of 20° to 60°.

23. The solar cell of claim 20, wherein the first and second anti-reflective layers include MgF₂ or LiF.

24. The solar cell of claim 20, wherein a difference between the first and second thicknesses is in a range of 10 nm to 100 nm.

25. The solar cell of claim 20, wherein the protrusion pattern has at least one of a pyramidal shape, a hemispheric shape and a triangular prism shape.

26. A solar cell comprising:
a back electrode layer;
a light absorbing layer on the back electrode layer;
a buffer layer on the light absorbing layer; and
a window layer disposed on the buffer layer and including a base layer and an anti-reflective pattern protruding from the base layer.

27. The solar cell of claim 26, wherein the anti-reflective pattern has a height in a range of 100 nm to 500 nm.

28. The solar cell of claim 26, wherein the anti-reflective pattern has a height corresponding to 10% to 50% of a thickness of the window layer.

29. The solar cell of claim 26, wherein the anti-reflective pattern includes first inclined surfaces and second inclined surfaces, which extend in a same direction while being inclined with respect to a top surface of the back electrode layer.

30. A method of fabricating a solar cell, the method comprising:
forming a back electrode layer on a substrate;
forming a light absorbing layer on the back electrode layer;
forming a window layer including a protrusion pattern on the light absorbing layer; and
forming first and second anti-reflective layers by depositing materials on the window layer while inclining a deposition direction of the materials.

31. The method of claim 30, wherein, in the forming of the first and second anti-reflective layers, the deposited materials are inclined at an angle of 20° to 60°.

32. The method of claim 30, wherein the protrusion pattern has a height in a range of 100 nm to 500 nm.
